(19) United States
(12) Patent Application Publication
(10) Pub. No.: US 2013/0108959 A1
(43) Pub. Date: May 2, 2013

(54) USE OF A COMPOSITION COMPRISING VINYL MONOMER-COMPRISING POLYMER, SOLVENT AND AT LEAST ONE HALOGEN-FREE BIOCIDE

(71) Applicants: Stephan Bauer, Hochheim (DE); Frank Fischer, Kirchheim (DE); Erik Bohrer, Maxdorf (DE)

(72) Inventors: Stephan Bauer, Hochheim (DE); Frank Fischer, Kirchheim (DE); Erik Bohrer, Maxdorf (DE)

(21) Appl. No.: 13/660,324

(22) Filed: Oct. 25, 2012

Related U.S. Application Data
(60) Provisional application No. 61/551,943, filed on Oct. 27, 2011.

(51) Int. Cl. C08L 39/06; C08L 39/04; C09K 5/00; C09D 139/06; C11D 3/60; G03F 7/004; C23C 16/00; C09D 139/04

(52) U.S. Cl. 430/270.1; 427/248.1; 523/122; 510/276; 252/73

(57) ABSTRACT

Use of a composition comprising vinyl monomer-comprising polymer, aqueous solvent and at least one biocide, wherein the biocide is halogen-free and soluble in the composition, for preparations in the field of laundry detergents and cleaners, membranes, gas hydrate inhibitors, ceramics, photoresists, gels, surface coatings, film coatings, displays, metalworking and metal production.

The present invention relates to the use of compositions comprising vinyl monomer-comprising polymer, aqueous solvent and at least one halogen-free biocide, in particular as metal coolant such as a metal quenching medium.

Aqueous polymer solutions such as solutions of vinyl lactam polymers, for instance polyvinylpyrrolidones, have to be admixed with suitable preservatives to achieve a guaranteed shelf life and storage conditions. The preservatives used must not have an adverse effect on the use of the polymer solution. The preservation of such polymer solutions is known to those skilled in the art. Preserved solutions are important wherever polymer solutions are used, stored or transported. Important fields of use are cosmetic preparations, preparations in the field of laundry detergents and cleaners, membranes, gas hydrate inhibitors, ceramics, photoresists, gels, surface coatings, film coatings, displays, metalworking and metal production.

The abovementioned applications often involve small amounts, relative to the total amount of a polymer produced, of polymers which are sold as solution for a specific application. From the point of view of a producer, it is therefore desirable to produce a polymer solution and stabilize it in such a way that many applications can be covered by one product. To achieve this, the product, viz. a stabilized aqueous polymer solution, has to meet the requirements of all these fields of use.

Accordingly, preservatives have to satisfy the requirements of ideally many, diversified, high-grade fields of use in order to make economical development, production and marketing of new polymer products possible at all.

Typical uses in the field of hair care are sprays, foams, mousses, gels and waxes. These applications and the preparations suitable for them are adequately known to those skilled in the art. Typical polymers used for these applications are likewise known, for example polyvinylpyrrolidones (vinylpyrrolidone homopolymers) and vinylpyrrolidone copolymers, such as copolymers of vinylpyrrolidone and vinyl acetate or of vinylpyrrolidone, vinylimidazole and methacrylamide.

The hardening of steels is a widespread method of influencing the quality of steel, e.g. hardness and toughness, in a targeted manner. For this purpose, the steel is firstly heated to about 850° C. On rapid and abrupt quenching in water, the steel transforms from the face centered cubic austenite crystal structure into the desired metastable tetragonally distorted body centered martensite crystal structure. The transformation commences at about 400° C. and is associated with a significant increase in the hardness of the steel. The transformation from the austenite structure into the martensite structure leads, firstly to a volume increase of up to 1%, as a result of which transformation stresses occur, in particular at the surface of the workpiece. Secondly, the quenching process brings about a volume contraction. Both lead to thermal stresses in the workpiece. These various stresses lead in the case of large components, e.g. gear crowns for wind turbines, to cracks and undesirable dimensional and shape changes. For this reason, water cannot be used as quenching medium for these components.

An alternative is provided by quenching oils. They allow rapid quenching down to about 400° C., at which the desired martensite formation commences. However, due to the reduced thermal conductivity of the oil, this is followed by significantly slower cooling. The stresses in the steel microstructure can be dissipated and the components have the desired hardness without deformation and cracks after quenching. Disadvantages of the quenching oils are the severe formation of soot and smoke during quenching and the fire risk associated therewith. In addition, the components have to be degreased after quenching.

A further alternative is provided by quenching media which are based on water-soluble polymers and do not have the disadvantages of the quenching oils or of water. An aqueous polymer solution comprising 1% by weight of polyvinylpyrrolidone (PVP) has, for example, a quenching behavior similar to that of quenching oil.

Owing to the high thermal stress during quenching and the long period of several years for which the quenching baths are used, these aqueous PVP polymer solutions have to be provided with satisfactory preservatives.

Metal coolants are, for example, metal quenching media and also liquids which are used for cooling metal articles and/or machining tools in metal machining such as cutting, milling, drilling.

Polymeric nitrogen-comprising preservatives such as Cosmocil CQ, which are used in industry as preservatives for aqueous PVP solutions have a high affinity for, for example, metal surface or for skin and hair. They therefore adversely affect the good film properties of the generally high molecular weight PVP solutions on contacting with surfaces having keratin structures, for instance hair and skin, or of metals. In the case of metals, this results in more rapid and thus undesirable cooling of the metal body, in particular in the temperature range from 400° C. to room temperature which is relevant for the hardening processes. Furthermore, these preservatives can coagulate and therefore interfere in the formation of a uniform polymer film, resulting in differing degrees of heat transfer and thus heat removal of differing rapidity in the workpiece.

Preservatives such as Cosmocil CQ® are associated with toxicological concerns. Preservatives comprising halogens, in particular those comprising halide ions such as chloride, for instance in Cosmocil CQ, can also lead to corrosion of the workpiece and of the quenching tank or to irritation of skin and hair. In the case of cosmetic preparations and also preparations in the electronics industry, the halide ions can also hinder production of a stable preparation, for instance as a result of undesirable precipitation of gels or solids, disruption of the gel structure leading to, for instance, a decrease in viscosity, or other undesirable interactions with other constituents.

The use of biocides for stabilization of, in particular aqueous polymer solutions in the field of hair cosmetics is known. Thus, the Internet publication IPCOM000202917D discloses a composition composed of three biocides and its use for stabilizing PVP and also the use of polymers which have been stabilized in this way in cosmetic preparations, in particular hair care preparations.

U.S. Pat. No. 3,902,929 discloses metal quenching baths comprising from 1 to 13% by weight of polyvinylpyrrolidone having an average molecular weight in the range from 5000 to 400 000 g/mol as water-soluble polymers.

U.S. Re Pat. No. 34,119 describes a metal quenching bath which comprises up to 25% by volume of a polyvinylpyrrolidone having an average molecular weight in the range from 1 270 000 to 2 240 000 g/mol as significant water-soluble polymer.

US-A 2009/65107 discloses metal quenching baths which comprise inorganic nanoparticles having an average diameter of from 0.2 to 10 μm, in particular sheet silicates such as talc, mica, montmorillonite, hectorite or saponite, and a water-soluble polymer, such as polyalkylene glycol, polyvinylpyrrolidone, polyacrylamide or polyvinyl alcohol as significant components.

US-A 2009/95384 relates to metal quenching baths based on vinylpyrrolidone-vinylcaprolactam copolymers in admixture with substituted oxazoline polymers, polyalkylene glycols and/or polyvinylpyrrolidones.

It was an object of the invention to discover preservatives for compositions comprising vinyl monomer-comprising polymer and aqueous solvent, in particular for use in metal quenching media, which do not have any adverse effects on film formation, in particular on the quenching behavior of metal quenching media. They should be toxicologically unproblematic. Furthermore, they should not be able to cause any damage, for instance as a result of corrosion, to an article which comes into contact with the composition and therefore should, in particular, not comprise any halide ions such as chloride. Furthermore, sufficient preserving stability against bacteria and fungi was desirable, both during handling of the pure polymer solution, for example during storage, and also in the preparation, for instance in metal quenching media.

We have found the use of a composition comprising vinyl monomer-comprising polymer, aqueous solvent and at least one biocide, wherein the biocide is halogen-free and soluble in the composition, for preparations in the field of laundry detergents and cleaners, membranes, gas hydrate inhibitors, ceramics, photoresists, gels, surface coatings, film coatings, displays, metalworking and metal production.

The composition according to the invention is preferably used for preparations in the field of metal coolants, in particular as metal quenching medium.

In the use of the composition according to the invention, the formation of polymer film on a surface which is brought into contact with the composition on evaporation of the solvent of the composition is preferably not disrupted by the biocide. Undesirable interactions with other constituents of a preparation are avoided or at least minimized.

Biocides used according to the invention are the following substances and solutions and mixtures comprising at least one of the substances mentioned:
a) alkyl-substituted aliphatic or aromatic alcohols and salts thereof, e.g. phenoxyethanol, benzyl alcohol, ethylhexylglycerol, 1,2-octanediol, 1,2-decanediol, 1,5-pentanediol, methyl 4-hydroxybenzoate, propyl 4-hydroxybenzoate, sodium 4-(methoxycarbonyl)phenoxide, sodium 4-(propyloxycarbonyl)phenoxide,
b) aliphatic or aromatic carboxylic acid salts such as alkali metal salts of sorbate and benzoate,
c) fat-soluble substances having antioxidative and non-antioxidative effects, in particular tocopherol and its isomers and derivatives,
d) nitrogen- and sulfur-comprising heterocycles, such as alkylisothiazolinones, such as 2-methylisothiazolinone, zinc bis[2-pyridinolate]N,N′-dioxide.

Such substances and mixtures of substances are commercially available, for example under the following brand names:
Euxyl® PE 9010, from Schülke & Mayr GmbH,
comprises 50-100% of 2-phenoxyethanol (CAS No. 122-99-6) and 2-10% of 3-(2-ethylhexyloxy)propane-1,2-diol (CAS 70455-33-9) as active compounds;
Euxyl® K220, from Schülke & Mayr GmbH,
comprises 70-80% of 3-(2-ethylhexyloxy)propane-1,2-diol (CAS 70455-33-9) and 7-8% of 2-methyl-2H-isothiazol-3-one (CAS No. 2682-20-4) as active compounds;
Euxyl® K 700, from Schülke & Mayr GmbH,
comprises 10-25% of potassium sorbate (CAS No. 24634-61-5), 25-50% of benzyl alcohol (CAS No. 100-51-6) and 25-50% of 2-phenoxyethanol (CAS No. 122-99-6) as active compounds;
Euxyl® K 701, from Schülke & Mayr GmbH,
comprises 75-85% of 2-phenoxyethanol (CAS No. 122-99-6), 10-15% of benzoic acid (CAS No. 65-85-0), 3-6-8% of acetyl-6-methyl-2H-pyran-2,4-(3H)-dione (CAS No. 520-45-6) and 1-3% of (ethylhexyloxy)propane-1,2-diol (CAS No. 70445-33-9) as active compounds;
Euxyl® K 712, from Schülke & Mayr GmbH,
comprises 10-25% of potassium sorbate (CAS No. 24634-61-5) as active compound;
Microcare® MT, from Thor GmbH,
comprises 9.5% of methyl-2H-isothiazol-3-one (CAS No. 2682-20-4) as active compound;
Microcare® MTD 1 and MTD 2, from Thor GmbH,
comprises 1,10-decanediol (CAS No. 112-47-0) and methyl-2H-isothiazol-3-one (CAS No. 2682-20-4) as active compounds;
Phenonip®, from Thor GmbH,
comprises 50-100% of 2-phenoxyethanol (CAS No. 122-99-6) as active compound;
Neolone® 950, from DOW Chemical,
comprises 9.5-9.9% of 2-methyl-4-isothiazolin-3-one (CAS No. 2682-20-4) as active compound;
Protector) PE, from BASF SE,
comprises at least 99% of 2-phenoxyethanol (CAS No. 122-99-6) as active compound;
Optiphen®, from ISP,
comprises 53-58% of 2-phenoxyethanol (CAS No. 122-99-6) and 42-47% of 1,2-octanediol (CAS No. 122-99-6) as active compounds.

Very particularly suitable biocides are those comprising 2-phenoxyethanol, 3-(2-ethylhexyloxy)propane-1,2-diol and/or 2-methyl-2H-isothiazol-3-one.

For the purposes of the present invention, preference is given to biocides which are halogen-free and are soluble in the composition. Preference is also given to selecting biocides which are soluble in water to give a clear solution and the preparations comprising polymer and biocide thus have a haze value determined as FTU value of less than 1. A further preferred property of the biocides is that, on evaporation of the solvent of the preparation, for instance a metal quenching medium, they do not interfere in the formation of a film of the polymer on the surface, for instance on the workpiece to be quenched, and thus allow, for example, uniform cooling of the workpiece and a comparatively smooth film on the article.

A further desirable property of the biocides is their regulatory approval for the intended use: this means that the biocide has to be toxicologically approved for the respective desired application. The biocide according to the invention therefore preferably has approval for use in preparations for industrial applications. This ensures the greatest possible safety in use. At the same time, the widest possible access of the preparation comprising polymer and biocide to fields of use is ensured.

Likewise, the preferred biocides have approval under the program for the safety of chemicals “REACH” of the European Union, end of April 2011 version. Furthermore, the preferred biocides have approval under the biocide regulations 98/8/EG of the European Parliament and the Council of Feb. 16, 1998.

For the purposes of the present invention, the term “biocide” comprises an individual chemical substance having a biocidal action or a mixture of a plurality of different individual substances and also formulations of one or more individual substances. The biocide is present in a concentration of the active compound, in the case of a plurality of active compounds the sum of the individual active compounds, of from 1 ppm to 50 000 ppm, preferably from 20 to up to 30 000 ppm, particularly preferably from 50 to up to 10 000 ppm, very particularly preferably from 100 to up to 5000 ppm and in particular from 200 to up to 3000 ppm, based on the total mass of the composition, in the composition used according to the invention.

Upper and lower limits can be combined with one another, for instance from 1 to 10 000 ppm or from 50 ppm to 5000 ppm. The range which is advisable to achieve stabilization, in particular against microorganisms, for the particular application depends on the biocide and can easily be determined for the particular case by a person skilled in the art using known test methods.

The biocide used according to the invention is soluble in the composition.

The solubility is determined according to the information in the German Pharmacopoeia, 10th edition (DAB 10), as is reproduced in Römpp:

Solubility Designations (Based on 20° C.) According to the DAB.

| | |
|---|---|
| Very soluble | = soluble in less than 1 part of solvent |
| Readily soluble | = soluble in 1-10 parts of solvent |
| Soluble | = soluble in 10-30 parts of solvent |
| Not readily soluble | = soluble in 30-100 parts of solvent |
| Sparingly soluble | = soluble in 100-1000 parts of solvent |
| Very sparingly soluble | = soluble in 1000-10 000 parts of solvent |
| Virtually insoluble | = soluble in more than 10 000 parts of solvent |

Preferred biocides are readily soluble in the composition according to the invention.

Particularly preferred biocides are very readily soluble in the composition according to the invention.

“Water-insoluble” and “insoluble” means, for the purposes of the present invention, that the polymer is sparingly soluble, very sparingly soluble or virtually insoluble as per the DAB.

A further preferred embodiment is the use of a composition according to the invention, wherein the K value of the vinyl monomer-comprising polymer changes by not more than 2 units and, in the case of a preparation comprising up to 20 percent by weight of vinyl monomer-comprising polymer, the viscosity changes by not more than 20%, the Hazen color number changes by not more than 20 and the pH changes by not more than 0.5 unit and the ash content is not more than 0.02 percent by weight as a result of the addition of the biocide.

The K value is a measure of the molar mass and is determined via the solution viscosity of an aqueous solution having a defined polymer concentration (see Volker Bühler in “Polyvinylpyrrolidone excipients for the pharmaceutical industry”, 9th revised edition, BASF, pages 26 to 29). It can only be determined for polymers which have a sufficient solubility in water.

Different polymers which have been polymerized from different monomers or even the same monomers but have different proportions of these monomers in the polymer usually have different molar masses, reported in grams per mole, despite the same K value. This fact is known to those skilled in the art.

Preference is given to the change in the K value not being more than one unit; particular preference is given to no change (within measurement accuracy) in the K value being observed.

The viscosity of such a preparation is determined rheologically by means of a viscometer as Brookfield apparent viscosity in accordance with DIN EN ISO 2555. A suitable measuring instrument is, for example, a Brookfield viscometer, model DV-III+, with RV spindle sets. The samples are usually brought to a solids content of 20 percent by weight, in the case of polymer solutions generally a solids content of polymers. The solutions are thermostatted at 23° C. for about one hour and then measured. After rotation for one minute, the measured value is determined.

The viscosity of the preparation used according to the invention changes as a result of the addition of the biocide by not more than 20%, preferably not more than 15%, particularly preferably not more than 10%, and very particularly preferably by not more than 5% based on the viscosity of the same preparation without addition of the biocide, or, for example, does not change at all.

The ash content is determined according to the determination of ash content as “sulfated ash content” known to those skilled in the art. The ash content is preferably not more than 0.01 percent by weight, particularly preferably not more than 0.005 percent by weight and very particularly preferably not more than 0.001 percent by weight.

The figure for the ash content is based on the total mass of the preparation used according to the invention.

The pH is determined according to general knowledge and applies to the preparation. The pH changes by not more than 0.5 unit, preferably by not more than 0.4 unit, particularly preferably not more than 0.3 unit, very particularly preferably not more than 0.2 unit and, for example, changes by not more than 0.1 unit or not at all.

The Hazen color number is determined according to general knowledge.

The figures for the viscosity of the preparation, the change in the K value, ash content and pH are here based on a preparation comprising not more than 20 percent by weight of polymer (calculated as polymer solids based on the total mass of the preparation).

These respective changes are determined by comparison of the measured results from the starting solution before and after addition of the biocide.

For the purposes of the present invention, the terms “aqueous solvent” and “solvent” are used synonymously and refer to water or a mixture of water and an organic solvent comprising at least 50 percent by weight of water, preferably at least 70 percent by weight, particularly preferably at least 90 percent by weight, very particularly preferably at least 95 percent by weight, of water and in particular consists exclusively of water.

For the purposes of the present invention, “water” comprises all types of water: water of industrial quality, water of naturally occurring quality such as surface water, river water or groundwater and also purified water. Purified (“pure”) water can be purified by purification methods such as single or multiple distillation, desalination, diffusion, adsorption, by means of ion exchangers and also activated carbon or other absorbents, by means of a filtration process such as ultrafiltration or dialysis. The term “pure” water usually refers to singly or multiply distilled water and also deionized water. Preference is given to using purified water.

For the purposes of the present invention, an “organic solvent” is a solvent which is made up of carbon, hydrogen and optionally oxygen and/or nitrogen atoms. The term solvent can refer to a single solvent or a mixture of a plurality of solvents. Typical representatives of organic solvents are, for instance, C1-C8-alcohols such as methanol, ethanol, n-propanol, isopropanol, butanol and isomers thereof, amino alcohols such as monoethanolamine, diethanolamine and triethanolamine, glycol, glycerol and also oligo- and polyethylene and -propylene glycols and their monoethers and diethers with, for example, alcohols.

As organic solvents, preference is given to using amino alcohols such as monoethanolamine, diethanolamine and triethanolamine, glycol, glycerol and also oligo- and polyethylene and -propylene glycols and also their monoethers and diethers with, for example, alcohols. Particular preference is given to oligo- and polyethylene and -propylene glycols and their monoethers and diethers with, for example, alcohols, with these substances still being liquid or pourable at 25° C.

The term “vinyl monomer-comprising polymer” comprises homopolymers, copolymers, graft homopolymers and graft copolymers.

Suitable vinyl monomers are vinyl amides such as vinyl lactams, acrylates, methacrylates, methacrylamides, acrylamides and monomers comprising amine groups and also monomers comprising sulfonic acid groups.

Preference is given to using vinyl amide polymers. Suitable vinyl amides are vinyl lactams and vinyl amides such as vinylformamide, vinylalkylamides such as vinylisopropylamide, vinylmethylamide and vinylbutylamide.

Particular preference is given to vinyl lactam polymers. Preferred vinyl lactam polymers comprise vinyl lactam together with no, one or more monomers a) and no, one or more monomers b). This means that the polymers have been obtained by polymerization of the monomers mentioned and can also comprise residual amounts of the monomers. A vinyl lactam polymer can be not only a vinyl lactam homopolymer but also a vinyl lactam copolymer of two or more different vinyl lactams.

Suitable vinyl lactams are, for example N-vinyl derivatives of the following lactams: 2-pyrrolidone, 2-piperidone, ε-caprolactam and alkyl derivatives thereof, for example 3-methyl-2-pyrrolidone, 4-methyl-2-pyrrolidone, 5-methyl-2-pyrrolidone, 3-ethyl-2-pyrrolidone, 3-propyl-2-pyrrolidone, 3-butyl-2-pyrrolidone, 3,3-dimethyl-2-pyrrolidone, 3,5-dimethyl-2-pyrrolidone, 5,5-dimethyl-2-pyrrolidone, 3,3,5-trimethyl-2-pyrrolidone, 5-methyl-5-ethyl-2-pyrrolidone, 3,4,5-trimethyl-2-pyrrolidone, 3-methyl-2-piperidone, 4-methyl-2-piperidone, 5-methyl-2-piperidone, 6-methyl-2-piperidone, 6-ethyl-2-piperidone, 3,5-dimethyl-2-piperidone, 4,4-dimethyl-2-piperidone, 3-methyl-ε-caprolactam, 4-methyl-ε-caprolactam, 5-methyl-ε-caprolactam, 6-methyl-ε-caprolactam, 7-methyl-ε-caprolactam, 3-ethyl-ε-caprolactam, 3-propyl-ε-caprolactam, 3-butyl-ε-caprolactam, 3,3-dimethyl-ε-caprolactam or 7,7-dimethyl-ε-caprolactam. Preferred vinyl lactams are N-vinylpyrrolidone, 3-methyl-N-vinylpyrrolidone, 4-methyl-N-vinyl-pyrrolidone, 5-methyl-N-vinylpyrrolidone, N-vinylpiperidone and N-vinylcaprolactam. Particularly preferred vinyl lactams are N-vinylpyrrolidone (“VP”) and N-vinylcaprolactam (“VCap”). Very particular preference is given to N-vinylpyrrolidone.

Preferred vinyl lactam polymers are vinylpyrrolidone polymers such as polyvinylpyrrolidones and vinylpyrrolidone copolymers. A preferred vinyl lactam copolymer comprising only vinyl lactams comprises N-vinylpyrrolidone and N-vinylcaprolactam.

Suitable monomers a) are, for example, N-vinyl amides such as N-vinylformamide and the N-vinylamine obtainable therefrom by hydrolysis after the polymerization, N-vinyl-N-methylacetamide, N-isopropylmethylacetamide; amines such as N-vinyl- or allyl-substituted heterocyclic compounds, preferably N-vinylpyridine, or N-allylpyridine, N-vinylimidazoles, which may also be substituted in the 2, 4 or 5 position by C1-C4-alkyl, in particular methyl or phenyl radicals, e.g. 1-vinylimidazole, 1-vinyl-2-methylvinylimidazole and their quaternized analogs such as 3-methyl-1-vinylimidazolium chloride, 3-methyl-1-vinylimidazolium methylsulfate, N—C1-C24-alkyl-substituted diallylamines or their quaternized analogs such as diallylammonium chloride or diallyldimethylammonium chloride.

Preferred monomers a) are vinyl amides such as vinylformamide and the vinylamine obtainable by hydrolysis after the polymerization, N-vinylimidazole, and vinylmethylamide.

Very particularly preferred monomers a) are vinylformamide and the vinylamine obtainable by hydrolysis after the polymerization and also N-vinylimidazole.

Polymers according to the invention can accordingly also be copolymers of at least one vinyl lactam and at least one monomer a) for example copolymers of N-vinylpyrrolidone and N-vinylimidazole, copolymers of N-vinylpyrrolidone and N-vinylformamide or copolymers of N-vinylpyrrolidone, N-vinylcaprolactam and N-vinylimidazole. Preferred copolymers are copolymers of N-vinylpyrrolidone and N-vinylimidazole.

Possible monomers b) are all the monomers designated as monomers b) on page 6, line 8 to page 8, line 17 of WO 2010/072640, which is hereby expressly incorporated by reference. In addition, acrylamides of the general structure

CH₂═C(R¹)—C(═O)—NR²R³,

where
R¹ to R³: are each, independently of one another, hydrogen or a linear or branched, optionally substituted C₁-C₁₀-alkyl radical,
   can also be used as monomers b).

Preferred monomers b) are maleic acid, maleic anhydride, acrylamide, methacrylamide, 2-hydroxyethyl(meth)acrylamide, 2-hydroxyethylethylacrylamide, isopropylmethacrylamide, N-tert-butylacrylamide, N-isopropylacrylamide, also vinyl esters of aliphatic C2-C18-carboxylic acids, e.g. vinyl acetate and also the vinyl alcohol obtainable therefrom by hydrolysis after the polymerization, vinyl propionate, vinyl butyrate, vinyl laurate, vinyl stearate, vinyl neononate “VEOVA 9” and vinyl neodecanoate “VEOVA 10”, also dimethylamino(m)ethyl(meth)acrylate and dimethylamino(m)ethyl(meth)acrylamide and their quaternized analogs and/or diallyldimethylammonium chloride.

The term “(m)ethyl(meth)acrylate” and variants thereof comprising only “(m)” or “(meth)” comprises, for the purposes of the present invention, the substances “methyl acrylate”, “ethyl acrylate”, “methyl methacrylate” and “ethyl methacrylate”. Derivatives comprising “(m)ethyl(meth)acrylate” have analogous meanings. The terms “(meth)acrylamide” and “(meth)acrylate” and the structures comprising these name components are likewise analogous thereto.

Particularly preferred monomers b) are acrylamide, methacrylamide, N-tert-butylacrylamide, N-isopropylacrylamide, vinyl acetate and also the vinyl alcohol obtainable by hydrolysis after the polymerization, vinyl propionate, vinyl neononate VEOVA 9 and vinyl neodecanoate VEOVA 10, dimethylamino(m)ethyl(meth)acrylate, dimethylamino(m)ethyl(meth)acrylamide.

Very particularly preferred monomers b) are methacrylamide, N-tert-butylacrylamide, N-isopropylacrylamide, vinyl acetate and/or vinyl alcohol, in particular methacrylamide, N-isopropylacrylamide and vinyl acetate.

Polymers, which are copolymers and comprise monomers b) can comprise one or more of the monomers b). However, a copolymer usually does not comprise more than five different monomers b).

Polymers according to the invention can accordingly also be copolymers of N-vinylpyrrolidone and vinyl acetate, copolymers of N-vinylpyrrolidone, vinylcaprolactam and vinyl acetate, copolymers of N-vinylcaprolactam and vinyl acetate or copolymers of N-vinylpyrrolidone and (meth)acrylamides. Preferred copolymers comprising monomers b) comprise N-vinylpyrrolidone and vinyl acetate, (meth)acrylamide, N-tert-butyl(meth)acrylamide and/or N-isopropyl(meth)acrylamide. Particularly preferred copolymers comprising monomers b) comprise N-vinylpyrrolidone and vinyl acetate, acrylamide, N-tert-butylacrylamide and/or N-isopropylacrylamide.

Preferred polymers also include copolymers which comprise at least one vinyl lactam, at least one monomer a) and at least one monomer b).

Particularly preferred polymers include copolymers which comprise at least one vinyl lactam and at least one monomer b) but no monomer a).

The vinyl lactams, monomers a) and b) used for the polymerization, can, independently of one another, be single monomers of the respective type or mixtures of a plurality of vinyl lactams, a plurality of monomers a) and/or b), with the respective proportion of vinyl lactams, monomers a) and b) indicating the proportion of vinyl lactam, monomer a) and monomer b), respectively, in the polymer.

The total amount of vinyl lactam, monomer a) and monomer b) always add up to 100 percent by weight based on the polymer.

The proportions in percent by weight based on the total mass of the polymer for monomers a) and monomers b) are, independently of one another, usually up to 80 percent by weight, preferably up to 70 percent by weight, particularly preferably up to 50 percent by weight, very particularly preferably up to 40 percent by weight and in particular up to 20 percent by weight or are, for example, not present in the polymer at all.

The composition used preferably comprises one or more vinyl lactam polymers. In a particularly preferred embodiment, the polymer is a vinylpyrrolidone polymer, for instance a polyvinylpyrrolidone homopolymer or a vinylpyrrolidone copolymer. In a very particularly preferred embodiment, the polymer is a polyvinylpyrrolidone.

Polyvinylpyrrolidones are, for example polymers having K values of from 10 to 200, preferably from K 20 to K 150, for example 12, 15, 17, 25, 30, 60, 80, 85, 90, 95, 100, 115, 120, 130, 150, 180.

Vinylpyrrolidone copolymers are for example, copolymers with N-vinylcaprolactam (VCap), vinyl acetate (VAc), N-vinylimidazole (VI), N-tert-butylacrylamide (TBAA) and/or N-isopropylacrylamide (IPAA) or mixtures thereof, e.g. copolymers of N-vinylpyrrolidone (VP) and vinyl acetate having a weight ratio of VP/VAc of from 20:80 to 80:20, for example 30:70, 50:50, 60:40, 70:30, and having K values of from 10 to 150, preferably from 15 to 80 and particularly preferably from 20 to 50. Particularly preferred copolymers of N-vinylpyrrolidone and vinyl acetate have a K value of from 25 to 60 and a weight ratio of VP:VAc of from 55:45 to 70:30, for example 60:40, 50:50 and 65:35, copolymers of VP and VCap in each case having K values of from 15 to 150, preferably from 20 to 120 and in particular from 30 to 110, and weight ratios of the monomers VP to VI or VP to VCap of from 95:05 to 20:80, preferably from 10:90 to 50:50, particularly preferably from 20:80 to 50:50 and also, for example, 30:70 with K values of from 10 to 200, preferably from 30 to 150 and particularly preferably from 60 to 120, and also copolymers of VP and TBAA or IPAA in each case having K values of from 15 to 150, preferably from 20 to 100 and in particular from 30 to 90, and also weight ratios of the monomers VP to TBAA or VP to IPAA of from 99:01 to 30:70, preferably from 5:90 to 50:50, particularly preferably from 10:80 to 30:70, and also, for example, 20:80 with K values of from 10 to 200, preferably from 30 to 150 and particularly preferably from 60 to 120.

In a preferred embodiment the vinyl monomer polymer used according to the invention, has a Fikentscher K value of at least 60.

In a further preferred embodiment, the vinyl monomer polymer used according to the invention has a Fikentscher K value of from 10 to 200, particularly preferably from 20 to 180, very particularly preferably from 60 to 150 and in particular from 80 to 130.

The preparation of vinyl lactam polymers by free-radical polymerization is known per se. The polymerization gives polymers which, depending on the monomer solubility and the physical structure (the three-dimensional arrangement of the polymer chains), are water-soluble, form a gel in water or are insoluble in water. The present invention comprises only water-soluble and gel-forming polymers. Preference is given to only water-soluble polymers.

The preparation of polyvinylpyrrolidones can be carried out, for example, as a solution or precipitation polymerization in a suitable solvent such as water, mixtures of water and organic solvents, for example ethanol/water or isopropanol/water mixtures, or in purely organic solvents such as methanol, ethanol or isopropanol. These preparative methods are known to those skilled in the art.

The compositions used according to the invention comprise, as significant component in addition to the biocides, at least one of the polymers according to the invention in a total amount, based on the total mass of the composition, of at least 1% by weight, preferably at least 5% by weight, particularly preferably at least 10% by weight, for example 15, 20, 25, 30, 35, 40, 45, 50 or even over 50% by weight. However, the compositions usually do not comprise more than 70% by weight of polymer, preferably not more than 50% by weight, particularly preferably not more than 40% by weight and very particularly preferably not more than 30% by weight, with compositions comprising high molecular weight polymers (i.e. polymers having molar masses as weight average molecular weight Mw of above about 300 000 g/mol) usually having not more than 25% by weight, preferably not more than 20% by weight and particularly preferably not more than 15% by weight, of polymer.

In a further embodiment which is preferred for use as metal coolant, in particular as metal quenching medium, the compositions according to the invention comprise, in addition to the biocides, at least one of the polymers according to the invention in a total amount of at least 0.1% by weight, preferably at least 0.2% by weight, particularly preferably at least 0.5% by weight, for example, 1 or 2% by weight, and also up to 10% by weight, preferably up to 7% by weight, particularly preferably up to 5% by weight and very particularly preferably up to 3% by weight.

Apart from solvents and at least one polymer according to the invention and a biocide, the compositions according to the invention can, particularly for use in the metal production, in particular as metal quenching medium, further comprise additives with which a person skilled in the art will be familiar, in particular antifoams such as silicone oils, fatty alcohol alkoxylates, alcohol alkoxylates, carboxylic esters or phosphoric esters and/or corrosion inhibitors, such as borax, sodium nitrite, amines, ammonium salts of organic acids, phosphoric esters, alcohol alkoxylates or 2-butyne-1,4-diol, and also further compounds such as ethanolamine, polyalkylene oxides, polyethylene glycols. In general, the total content of the customary additives in such an aqueous metal quenching medium is in the range from 0.1 to 20% by weight.

The preparations according to the invention for use as metal quenching medium therefore advantageously comprise at least 70 and not more than 99.8% by weight of water, at least 0.1 and not more than 10% by weight of polymer according to the invention, one or more of the biocides that are preferred according to the invention and at least 0.1 and not more than 20% by weight of customary additives.

The way in which the preparations according to the invention are employed as metal quenching medium is also well known to those skilled in the art. Thus, for example, a preparation according to the invention can be sprayed or sprinkled onto a metal article to be cooled (quenched). It is also possible to pass a metal article to be quenched through a down-flowing liquid film of a preparation according to the invention. However, a metal article to be quenched is particularly advantageously dipped into a preparation according to the invention and thereby cooled (“quenched”), as a result of which the heat energy is particularly efficiently removed.

The composition used according to the invention as metal quenching medium preferably has at a content of polymer solids of 1% by weight, a cooling rate at 550° C. of at least 75° C./second and at 350° C. not more than 75° C./second.

The composition used according to the invention as metal quenching medium particularly preferably has, at a content of polymer solids of 1% by weight, a cooling rate at 550° C. of at least 80° C./second and at 350° C. not more than 50° C./second.

The composition used according to the invention as metal quenching medium very particularly preferably has, at a content of polymer solids of 1% by weight, a cooling rate at 550° C. of at least 90° C./second and at 350° C. not more than 40° C./second.

The composition according to the invention is used, in particular, as metal quenching medium for the hardening of metal.

It has been found that the biocides used according to the invention allow the desired stabilization of the compositions used according to the invention. Adverse effects on the properties of the polymer in aqueous polymer solution, in particular formation or worsening of odor or color, an increase or decrease in the viscosity, K value and pH and an increase in the ash content, can also generally be virtually entirely or entirely avoided (within the respective accuracy of the measurement methods). Precipitates or corrosion of the metal articles which come into contact with the preparation has also not been observed.

Stabilization of the composition according to the invention, in particular, a metal quenching medium, for instance during storage, has likewise been achieved. This stabilization is achieved during storage: no changes in the abovementioned parameters is therefore able to be measured even after storage of these solutions for 3 months at 20° C. Furthermore, the stabilization is also achieved when a preparation according to the invention is used as metal quenching medium. Furthermore, only small influences, if any, on the quenching process have been found in quenching processes. “Stabilization” therefore also means that the properties of the composition as can be used, for instance, as metal quenching medium, both the physicochemical properties of the composition and also its properties during use, for instance as metal quenching medium in a quenching process, do not change or change only insignificantly. In particular, no change or no significant change in the cooling rates takes place.

### EXAMPLES

The following compounds were used for the examples:

Polymer: LUVITEC® K 90, 20% solution: aqueous polyvinylpyrrolidone solution having a solids content of 20.0% and a K value of 97 from BASF SE, CAS No. 9003-39-8

Biocides Used:

Cosmocil® CQ (comparison), (Producer Arch; INCI name Polyaminopropyl Biguanide; chemical name: polyhexamethylenebiguanide hydrochloride; 20 percent by weight in water)

Euxyl® PE9010

Euxyl® K220

Microcare® MT.

Determination of the Quenching Behavior

The quenching behavior of the quenching media was determined by means of the “Smart Quench” system from IVF. The portable testing system comprises a test rod which has a total length of 400 mm. The test element, which has a diameter of 12.5 mm, a length of 60 mm and a weight of 240 g, is located at the tip of the test rod. This test element comprises a nickel-based alloy “Inconel 600”. A thermocouple is installed in the interior of the test element. The cooling curves of the quenching media can in this way be measured and evaluated using an attached computer. The test element meets the international standard ISO 9950 and the American standards ASTM D 6200-97 and ASTM D 6482-99.

To carry out the measurement, the test element was heated to a temperature of 860° C. in an induction furnace and subsequently immersed in the associated circulation facility comprising 1.5 liters of the appropriate quenching medium. The quenching media have a temperature of 23° C. before commencement of the measurement. The stirring rate of the circulation facility was set to 1000 revolutions per minute during the measurements. The cooling measurements were started automatically at 850° C. The total measurement time was in each case 20 seconds.

### Comparative Examples 1 to 4 and Examples 1 to 9

An aqueous LUVITEC® K 90, 20% by weight, solution having a solids content of 20% by weight was diluted with water to a solids content of 1% by weight (LUVITEC® K 90, 1% solution for short). The quantities of biocide specified in Table 1 were added and stirred in. 1.5 liters of this solution were introduced into the circulation facility. The quenching curves were measured as described.

The measurements on the further quenching media as indicated in table 1 were carried out analogously. The cooling rates are shown in table 2.

TABLE 1
Quenching media
(“%” in each case means “percent by weight of solid polymer based
on the total mass of the preparation”; ppm are based on the total mass
of the preparation, calculated on the basis of the biocide used as
commercially available)

| | |
|---|---|
| Comparative | LUVITEC ® K 90, 1% solution |
| example 1 | |
| Comparative | LUVITEC ® K 90, 1% solution with 12.5 ppm Cosmocil |
| example 2 | CQ |
| Comparative | LUVITEC ® K 90, 1% solution with 62.5 ppm Cosmocil |
| example 3 | CQ |
| Comparative | LUVITEC ® K 90, 1% solution with 125 ppm Cosmocil |
| example 4 | CQ |
| Example 1 | LUVITEC ® K 90, 1% solution with 250 ppm Euxyl |
| | PE 9010 |
| Example 2 | LUVITEC ® K 90, 1% solution with 1250 ppm Euxyl |
| | PE 9010 |
| Example 3 | LUVITEC ® K 90, 1% solution with 2500 ppm Euxyl |
| | PE 9010 |
| Example 4 | LUVITEC ® K 90, 1% solution with 50 ppm Euxyl K220 |
| Example 5 | LUVITEC ® K 90, 1% solution with 250 ppm Euxyl K220 |
| Example 6 | LUVITEC ® K 90, 1% solution with 500 ppm Euxyl K220 |
| Example 7 | LUVITEC ® K 90, 1% solution with 50 ppm Microcare |
| | MT |
| Example 8 | LUVITEC ® K 90, 1% solution with 250 ppm Microcare |
| | MT |
| Example 9 | LUVITEC ® K 90, 1% solution with 500 ppm Microcare |
| | MT |

TABLE 2
Cooling rates

| | Cooling rate at | | |
|---|---|---|---|
| | 550° C. | Cooling rate at | Maximum cooling |
| | in ° C./s | 350° C. in ° C./s | rate in ° C./s |
| Comparative | 114 | 26 | 153 |
| example 1 | | | |
| Comparative | 119 | 27 | 165 |
| example 2 | | | |
| Comparative | 135 | 24 | 159 |
| example 3 | | | |
| Comparative | 140 | 22 | 165 |
| example 4 | | | |
| Example 1 | 125 | 25 | 157 |
| Example 2 | 114 | 24 | 165 |
| Example 3 | 110 | 24 | 170 |
| Example 4 | 134 | 23 | 168 |
| Example 5 | 114 | 25 | 159 |
| Example 6 | 111 | 24 | 168 |
| Example 7 | 142 | 22 | 169 |
| Example 8 | 134 | 27 | 168 |
| Example 9 | 131 | 26 | 164 |

The results show that equally good or even slightly better values were achieved despite replacement of the biocides.

TABLE 3
Properties of the compositions

| | | | Euxyl PE | Euxyl | | | | | | | Ash |
|---|---|---|---|---|---|---|---|---|---|---|---|
| Comparative | | Cosmocil CQ | 9010 | K220 | Microcare MT | | Color | Viscosity | K | | content |
| example | Example | in ppm | in ppm | in ppm | in ppm | Odor | Hazen | in mPa · s | value | pH | in % |
| 5 | | 0 | 0 | 0 | 0 | + | 17 | 27600 | 96.6 | 8.7 | <0.02 |
| 6 | | 12.5 | 0 | 0 | 0 | + | 18 | 27600 | 96.5 | 8.7 | <0.02 |
| 7 | | 62.5 | 0 | 0 | 0 | ∘ | 20 | 27550 | 96.5 | 8.6 | <0.02 |
| 8 | | 125 | 0 | 0 | 0 | ∘ | 23 | 27500 | 96.4 | 8.5 | <0.02 |
| | 10 | 0 | 250 | 0 | 0 | + | 17 | 27600 | 96.5 | 8.7 | <0.02 |
| | 11 | 0 | 1250 | 0 | 0 | + | 17 | 27400 | 96.4 | 8.7 | <0.02 |
| | 12 | 0 | 2500 | 0 | 0 | + | 17 | 27300 | 96.6 | 8.6 | <0.02 |
| | 13 | 0 | 0 | 50 | 0 | + | 17 | 27600 | 96.5 | 8.7 | <0.02 |
| | 14 | 0 | 0 | 250 | 0 | + | 16 | 27500 | 96.5 | 8.6 | <0.02 |
| | 15 | 0 | 0 | 500 | 0 | + | 17 | 27400 | 96.4 | 8.5 | <0.02 |
| | 16 | 0 | 0 | 0 | 50 | + | 17 | 27600 | 96.6 | 8.7 | <0.02 |
| | 17 | 0 | 0 | 0 | 250 | + | 16 | 27550 | 96.5 | 8.7 | <0.02 |
| | 18 | 0 | 0 | 0 | 500 | + | 17 | 27450 | 96.4 | 8.5 | <0.02 |

Notes for Table 3:
The odor was determined and assessed by sense of smell:
++ does not smell/
+ smells slightly pleasant/
∘ smells/
− smells distinctly, slightly musty/
−− smells very strong, musty
The viscosity was determined as Brookfield RVT, measured using spindle 7 at 100 rpm and 23° C., in accordance with DIN EN ISO 2555
The Fikentscher K value was determined in 1% strength solution in water.
The pH was determined as 10% strength by weight solution in water, in accordance with Ph. Eur. 2.2.3 at 20° C.
The Hazen color number of the undiluted sample was determined in accordance with DIN EN ISO 6271-2.
Ash content: gravimetric determination on a sample after 6 hours at 800° C.

The results in table 3 show that color and odor become, particularly compared to the medium and higher concentrations of Cosmocil CQ, better or at least do not deteriorate despite a significantly higher concentration of biocide.

The stability values, on the other hand, remain unchanged: the biocides display no influence on the physicochemical parameters and thus the stability of the polymer solutions on storage. The ash content, too, remains below the relevant limit, despite sometimes significantly higher amounts of biocide used.

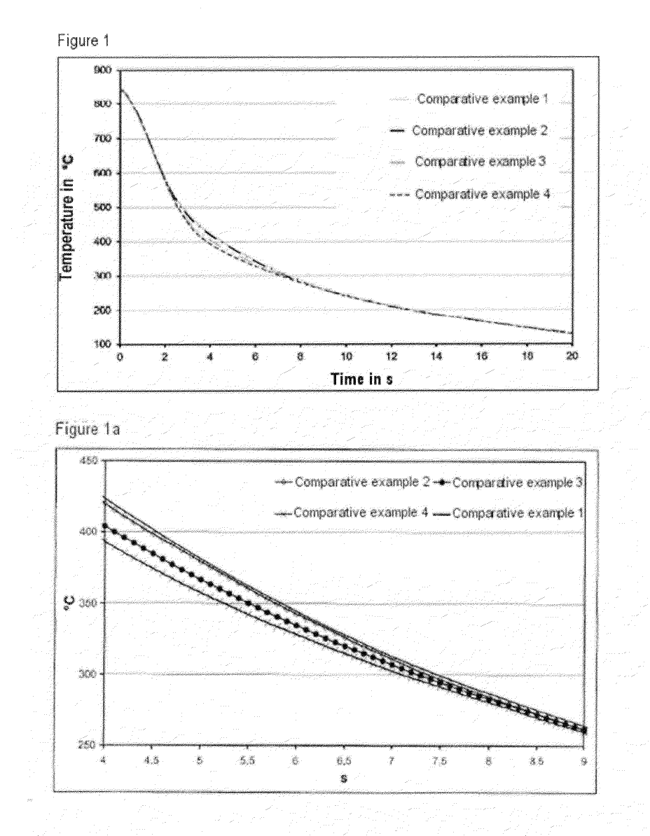

FIGS. 1 to 8 show the cooling curves associated with the experiments:

FIGS. 1 and 1a: Cooling curves for comparative examples 1-4

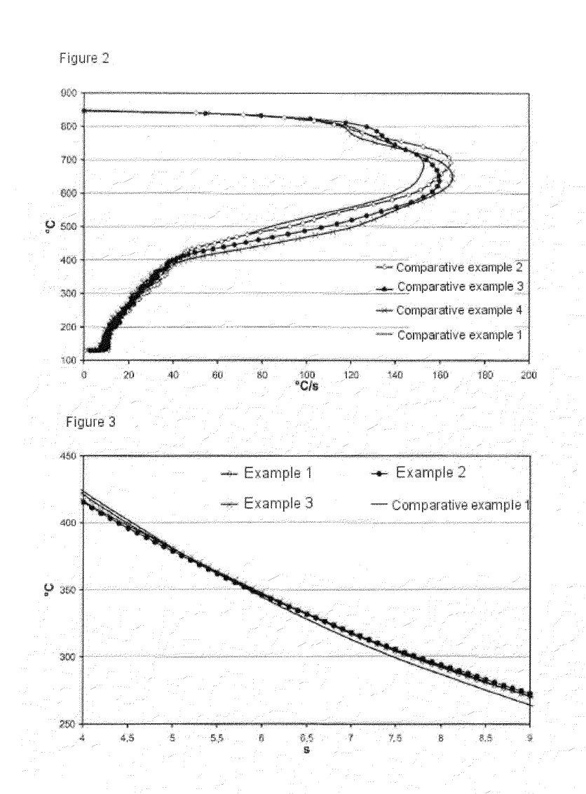

FIG. 2: Cooling rate as a function of temperature for comparative examples 1-4

FIG. 3: Cooling curves for comparative example 1 and examples 1-3

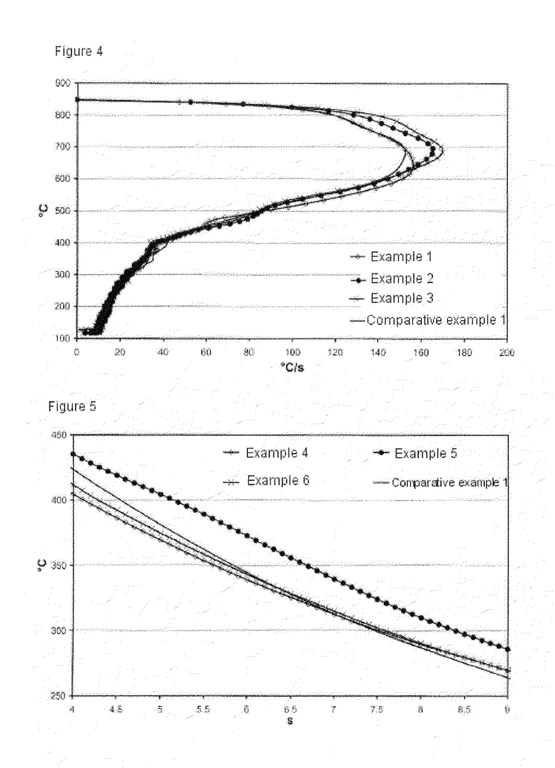

FIG. 4: Cooling rate as a function of temperature for comparative example 1 and examples 1-3

FIG. 5: Cooling curves for comparative example 1 and examples 4-6

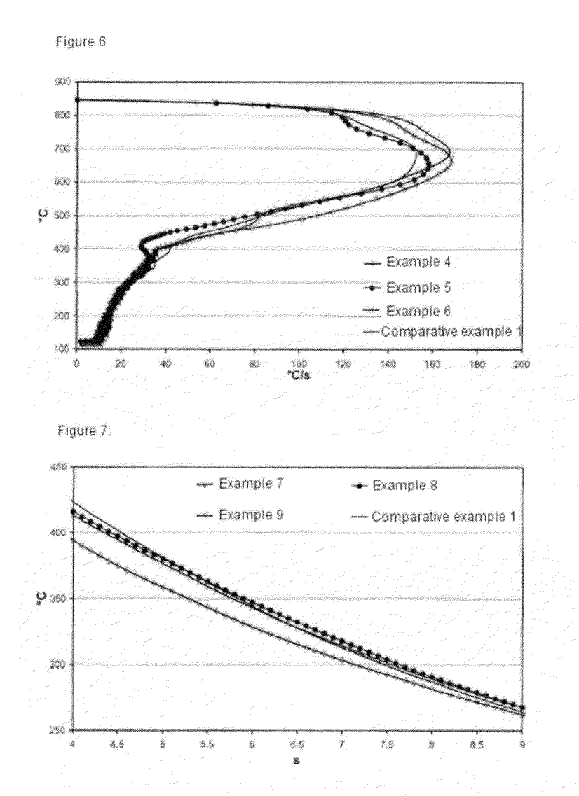

FIG. 6: Cooling rate as a function of temperature for comparative example 1 and examples 4-6

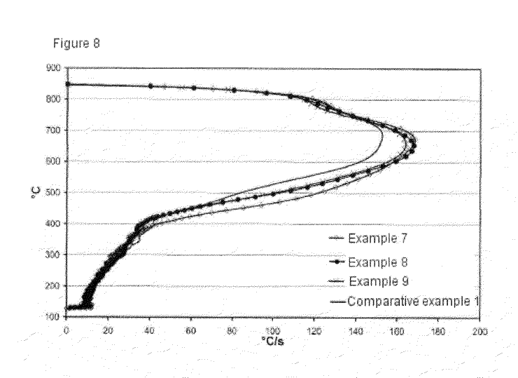

FIG. 7: Cooling curves for comparative example 1 and examples 7-9

FIG. 8: Cooling rate as a function of temperature for comparative example 1 and examples 7-9.

Proceeding from the abovementioned teachings, numerous changes to and modifications of the present invention are possible. It can therefore be assumed that the invention can be, within the scope of the accompanying claims, carried out in ways other than those specifically described herein.

1. The use of a composition comprising vinyl monomer-comprising polymer, aqueous solvent and at least one biocide, wherein the biocide is halogen-free and soluble in the composition, for preparations in the field of laundry detergents and cleaners, membranes, gas hydrate inhibitors, ceramics, photoresists, gels, surface coatings, film coatings, displays, metalworking and metal production.

2. The use of a composition according to claim 1 for preparations in the field of metal coolants.

3. The use of a composition according to claim 2 as metal quenching medium.

4. The use of a composition according to any of claims 1 to 3, wherein the formation of polymer film on a surface which is brought into contact with the composition on evaporation of the solvent of the composition is not disrupted by the biocide.

5. The use of a composition according to any of claims 1 to 4, wherein the biocide is present in a concentration of from 1 ppm to 10 000 ppm based on the total mass of the composition.

6. The use of a composition according to any of claims 1 to 5, wherein the K value of the vinyl monomer-comprising polymer changes by not more than 2 units and, in the case of a preparation comprising up to 20 percent by weight of vinyl monomer-comprising polymer, the viscosity changes by not more than 20%, the Hazen color number changes by not more than 20 and the pH changes by not more than 0.5 unit and the ash content is not more than 0.02 percent by weight as a result of the addition of the biocide.

7. The use of a composition according to any of claims 1 to 6, wherein the polymer is a vinyl lactam polymer.

8. The use of a composition according to claim 7, wherein the polymer is a vinylpyrrolidone polymer.

9. The use of a composition according to claim 8, wherein the polymer is a polyvinylpyrrolidone.

10. The use of a composition according to any of claims 1 to 9, wherein the polymer has a Fikentscher K value of from 10 to 200.

11. The use of a composition according to any of claims 1 to 10, wherein the polymer has a Fikentscher K value of at least 60.

12. The use of a composition according to any of claims 3 to 11, wherein, at a content of polymer solids of 1% by weight, the cooling rate at 550° C. is at least 75° C./s and at 350° C. is not more than 75° C./s.

13. The use of a composition according to any of claims 3 to 12 for the hardening of metal.
